(19) United States
(12) Patent Application Publication
(10) Pub. No.: US 2022/0392876 A1
(43) Pub. Date: Dec. 8, 2022

(54) LIGHT EMITTING DEVICE

(71) Applicants: EPISTAR CORPORATION, Hsinchu (TW); Yenrich Technology Corporation, Hsinchu County (TW)

(72) Inventors: Min-Hsun HSIEH, Hsinchu (TW); Hsin-Mao LIU, Hsinchu City (TW); Li-Yuan HUANG, Hsinchu (TW); Tzu-Hsiang WANG, Hsinchu (TW); Chi-Chih PU, Hsinchu (TW); Ya-Wen LIN, Hsinchu (TW); Hsiao-Pei CHIU, Hsinchu (TW); Pei-Yu LI, Hsinchu (TW)

(21) Appl. No.: 17/830,268

(22) Filed: Jun. 1, 2022

(30) Foreign Application Priority Data
Jun. 2, 2021 (TW) 110119953

(51) Int. Cl. H01L 25/075; H01L 33/62

(52) U.S. Cl. CPC H01L 25/0753; H01L 33/62; H01L 24/16

(57) ABSTRACT

A light-emitting device includes a first carrier, which includes a side surface between a first surface and a second surface, upper conductive pads on the first surface, and lower conductive pads under the second surface; a RDL pixel package includes a RDL which includes bonding pads and bottom electrodes, and the light-emitting units on the RDL, and connected to the bonding pads. A light-transmitting layer on the RDL and covers the light-emitting units, an upper surface, a lower surface, and a lateral surface between the upper surface and the lower surface. The RDL pixel package is on the first surface and electrically connected to the upper conductive pads. A protective layer covers the first surface and contacting the side surface of the RDL pixel package. The lower electrodes and the upper conductive pads are connected, and the distance between two adjacent bonding pads is less than 30 μm.

### CROSS-REFERENCE TO RELATED APPLICATIONS

This application claims priority to the benefit of Taiwan Patent Application Number 110119953 filed on Jun. 2, 2021, and the entire contents of which are hereby incorporated by reference herein in its entirety.

### BACKGROUND OF THE APPLICATION

### Field of the Disclosure

The present disclosure relates to a package, a display module, and manufacturing methods thereof, and particular to a light-emitting diode package for serving as a pixel display unit, a display module including the light-emitting diode package, and manufacturing methods thereof.

### Description of the Related Art

FIG. 1 is a conventional light-emitting diode (LED) display module, including a base 1 and a plurality of pixel packages 2 arranged as an array and affixed on the base 1. A path g1 is between adjacent pixel packages 2, and wider path g1 is beneficial for repairing the damaged pixel packages 2 subsequently.

Each of the pixel packages 2 includes a substrate 20, one group of pixels 2P on the substrate 20, and a light-transmitting layer 24 on the substrate 20 and covering the pixels 2P. Each group of the pixels 2P includes light-emitting units 21, 21′, and 21″, such as light-emitting diodes, that can respectively emit red light, blue light, and green light. The pixels 2P may be controlled by independent signals to emit red light, blue light, and green light for serving as a display pixel in the display module. A distance between the centers of adjacent pixel packages 2 is called a pixel gap g. When the size of the display module is fixed, a higher image resolution of the display module means more pixel packages 2 per unit area of the display module. If the pixel gap g is smaller, the space in the pixel packages 2 for accommodating the light-emitting units 21, 21′, and 21″ is also smaller. When the pixel gap g is less than 600 μm, the length of the light-emitting units 21, 21′, or 21″ could be less than 100 μm. In LED industry, LED having length less than or equal to 100 μm is often called mini LEDs or micro LEDs. The gap between positive and negative electrodes of a mini LED or micro LED is typically less than 30 μm. However, the precision of printed circuit board (such as a BT circuit board or an HDI circuit board) that is usually used as the substrate 20 in the industry is insufficient, and the gap between the positive and negative electrodes usually cannot be less than 30 μm, so they cannot be used as carriers for a mini LED or micro LED. For the mini LED or micro LED with a gap of less than 30 μm between the positive and negative electrodes, a re-distribution layer (RDL) structure is often used. After the light-emitting units 21, 21′, and 21″ are arranged, the RDL structure is disposed underneath the light-emitting units 21, 21′, and 21″ to serve as the substrate 20, and then an upper light-transmitting layer 24 is formed on the RDL structure to cover the light-emitting units 21, 21′, and 21″ for forming the pixel package 2.

### BRIEF SUMMARY OF THE DISCLOSURE

A light-emitting device includes a first carrier, which includes a first surface, a second surface, a side surface between the first surface and the second surface, a plurality of upper conductive pads on the first surface, and a plurality of lower conductive pads under the second surface; a RDL pixel package including a RDL (Re-Distribution Layer), which includes a plurality of bonding pads and a plurality of bottom electrodes, a plurality of light-emitting units located on the RDL and connected to the plurality of bonding pads, a light-transmitting layer located on the RDL and covering the plurality of light-emitting units, an upper surface, a lower surface, and a lateral surface located between the upper surface and the lower surface, wherein the RDL pixel package is located on the first surface of the first carrier and electrically connected to the plurality of upper conductive pads of the first carrier; and a protective layer covering the first surface of the first carrier and contacting the lateral surface of the RDL pixel package; wherein, the plurality of lower electrodes and the plurality of upper conductive pads of the first carrier are connected, and a distance between any two adjacent bonding pads is less than 30 μm.

### BRIEF DESCRIPTION OF THE DRAWINGS

FIG. 1 is a schematic view of a conventional display module.

FIG. 2A is a top view of a circuit board.

FIG. 2B is a cross-sectional view along line AA′ in FIG. 2A.

FIG. 2C shows a bottom surface of a re-distribution layer.

FIG. 3A and FIG. 3B shows structure of the region R in the re-distribution layer.

FIG. 4 shows the structure of the light-emitting unit.

FIG. 5 shows the structure of the light-transmitting layer covering the re-distribution layer and the light-emitting unit.

FIG. 6 shows steps of cutting the regions R into independent pixel packages.

FIG. 7A to FIG. 7C show process steps of pixel packages in accordance with an embodiment.

FIG. 8A to FIG. 8C show process steps of pixel packages in accordance with an embodiment.

FIG. 9A shows the structure of a display unit in accordance with an embodiment.

FIG. 9B shows the structure of a display unit in accordance with an embodiment.

FIG. 10A shows the structure of a pixel package in accordance with an embodiment.

FIG. 10B shows the structure of a pixel package in accordance with an embodiment.

FIG. 11A shows the structure of a pixel package in accordance with an embodiment.

FIG. 11B shows the structure of a pixel package in accordance with an embodiment.

FIG. 11C shows the structure of a pixel package in accordance with an embodiment.

FIG. 12A to 12C show the structure of a pixel package in accordance with an embodiment.

FIG. 13 shows the structure of a display unit in accordance with an embodiment.

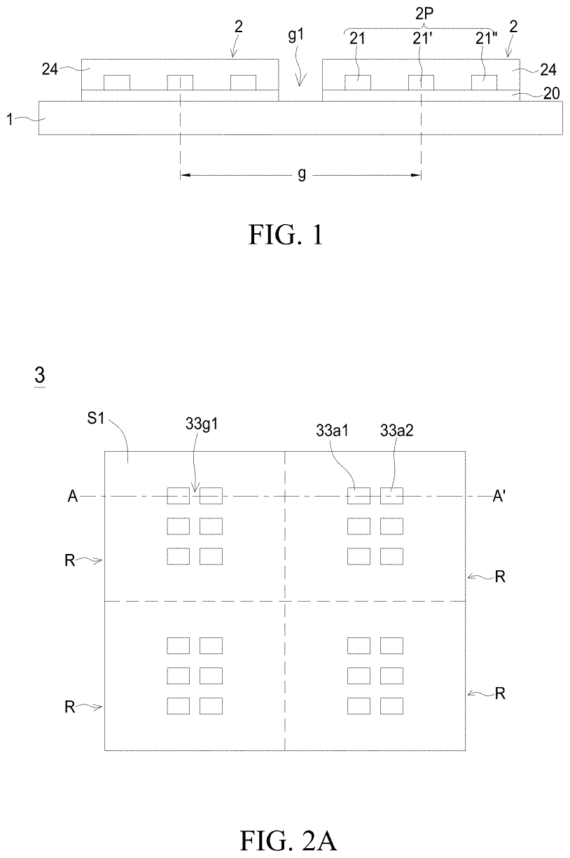

### DETAILED DESCRIPTION OF THE DISCLOSURE

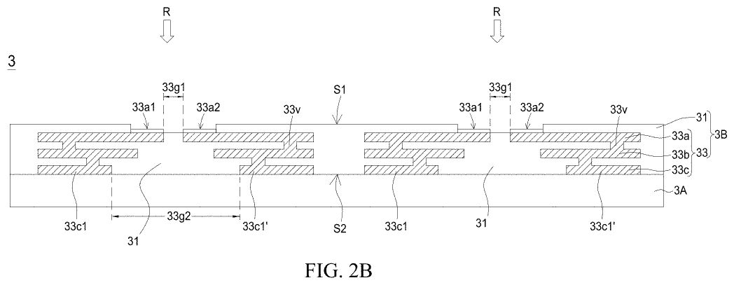

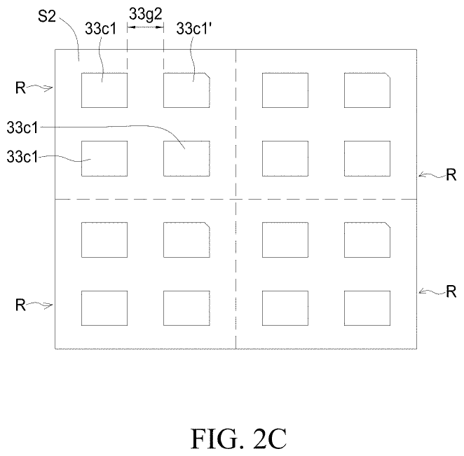

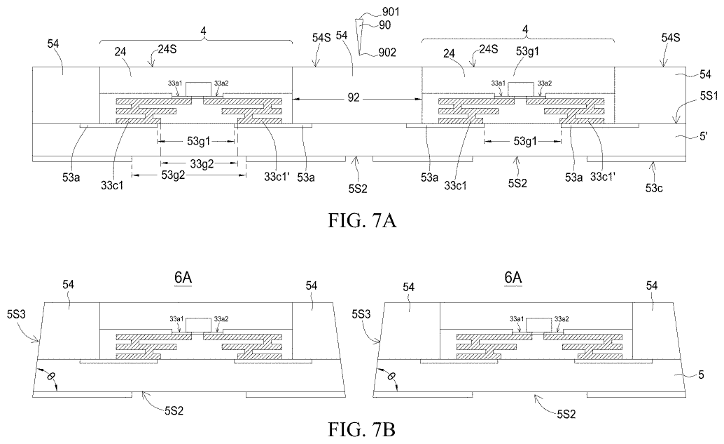

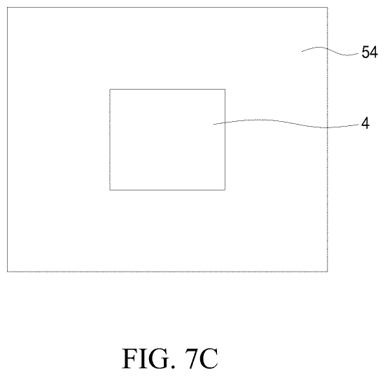

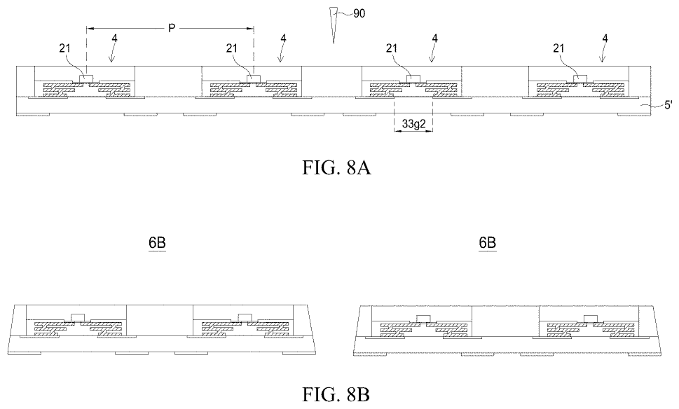

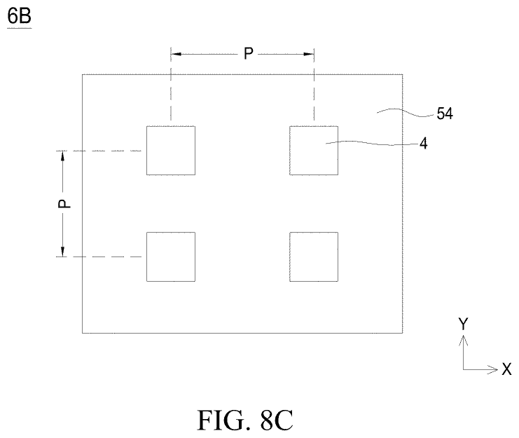

FIG. 2A to FIG. 8B show a schematic process flow of multi-substrate pixel packages 6A and 6B (shown in FIG. 7B and FIG. 8B). As shown in FIG. 2A and FIG. 2B, a circuit board 3 is provided, wherein FIG. 2A shows a top view of the circuit board 3, and FIG. 2B shows a cross-sectional view along line AA′ in FIG. 2A. As shown in FIG. 2A, the circuit board 3 includes a plurality of regions R. As shown in a cross-sectional view of FIG. 2B, the circuit board 3 includes a temporary substrate 3A and a re-distribution layer (RDL) 3B disposed on the temporary substrate 3A. The RDL 3B includes an upper surface S1 and a lower surface S2 opposite to the upper surface S1. The RDL 3B is affixed on the temporary substrate 3A by the lower surface S2, wherein the affixing method includes adhering with thermal release glue, UV glue, release glue, or electrostatic force. In the subsequent processes, the temporary substrate 3A may be separated from the RDL 3B without damaging the RDL 3B. The RDL 3B includes an insulating layer 31 and a circuit structure 33 embedded in the insulating layer 31, wherein the circuit structure 33 includes a upper circuit layer 33a, a lower circuit layer 33c, a middle circuit layer 33b disposed between the upper circuit layer 33a and the lower circuit layer 33c, and a plurality of vias 33v electrically connected to the upper circuit layer 33a, the lower circuit layer 33c, and the middle circuit layer 33b . The upper circuit layer 33a includes a plurality of bonding pads 33a1, 33a2 exposed from the upper surface S1 and not covered by the insulating layer 31, and the pads 33a1, 33a2 are electrically connected to the LED units in subsequent processes. The lower circuit layer 33c includes a plurality of lower electrodes 33c1, 33c1′ exposed from the lower surface S2 and not covered by the insulating layer 31. The material of the insulating layer 31 includes polyimide (PI), or Ajinomoto Build-up Film (ABF), and the material of the circuit structure 33 includes Cu, Ag, or Al.

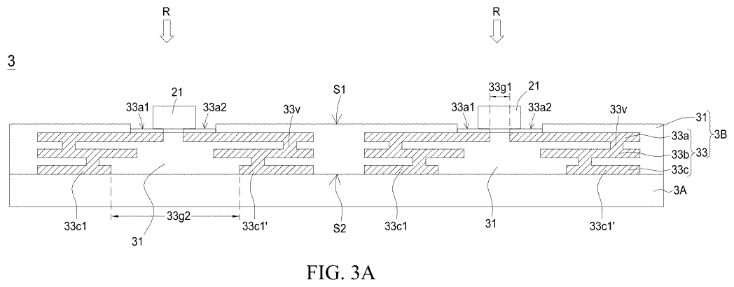

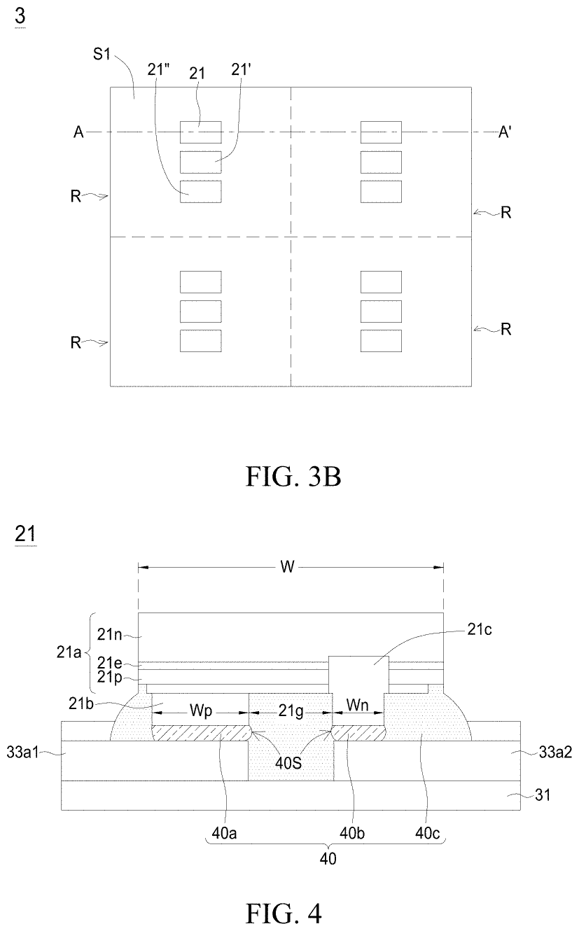

As shown in FIG. 2A, the upper surface S1 of the RDL 3B includes a plurality of regions R, and each of the regions R includes at least three pairs of bonding pads 33a1, 33a2 connecting to the light-emitting units 21 (such as light-emitting diodes or laser diodes) in subsequent processes, as shown in FIG. 3A. In each pair of the bonding pads 33a1, 33a2, the bonding pads 33a1, 33a2 are separated and electrically insulated from each other before bonded to the light-emitting unit. Since the circuit structure 33 of the RDL 3B is produced by semiconductor-level RDL processes which includes defining conductive patterns by photolithography and forming the circuit by electroplating and etching, the minimum metal line width and minimum pitch of the circuit can reach 15 μm, which is different from conventional printed circuit board processes. The conventional printed circuit board processes transfers copper foil to plastic board, of which the minimum metal line width and the minimum gap are about 30 μm. Therefore, a minimum distance 33g1 between the two bonding pads 33a1, 33a2 may be less than 30 μm to be connected to a chip, such as mini LED or micro LED, having a gap between the positive and negative electrodes less than 30 μm in subsequently processes.

As shown in FIG. 2C, each region R on the bottom surface S2 of the RDL 3B includes at least three first lower electrodes 33c1 and at least one second lower electrode 33c1′. A minimum electrode gap 33g2 between any two adjacent lower electrodes 33c1 and 33c1′ is greater than the minimum distance 33g1 between the adjacent bonding pads 33a1, 33a2 for connecting to one chip on the upper surface S1. In an embodiment, as shown in FIG. 7A, the lower electrodes 33c1 and 33c1′ are connected to upper conductive pads 53a of an external carrier 5′, and the minimum electrode gap 33g2 between the adjacent lower electrodes 33c1 and 33c1′ is corresponding to a minimum gap 53g1 between two adjacent upper conductive pads 53a. When the external carrier 5′ is a conventional printed circuit board, the minimum gap 53g1 is larger than 30 μm so the electrode gap 33g2 is also greater than 30 μm. The RDL 3B may bridge two structures with different dimensions, tolerances, or accuracies. In an embodiment, one side of the RDL 3B connects to a structure with smaller dimension, and the other side of the RDL 3B connects to a structure with larger dimension. In an embodiment, one side of the RDL 3B connects to a structure with tight tolerances, and the other side of the RDL 3B connects to a structure with wide tolerances. In an embodiment, one side of the RDL 3B connects to a structure with narrow circuit line width and gap, and the other side of the RDL 3B connects to a structure with wider circuit line width and gap. In other words, the RDL 3B enlarges the minimum distance 33g1 between the bonding pads 33a1, 33a2 to the electrode gap 33g2 between the lower electrodes 33c1 and 33c1′ through the circuit structure 33.

In each region R, the second lower electrode 33c1′has a different shape than other first lower electrodes 33c1, which allows the user to identify the position of the positive and negative electrodes. For example, the lower electrode 33c1′ and the lower electrodes 33c1 have different shapes in FIG. 2C. In an embodiment, the three lower electrodes 33c1 are square, and the lower electrode 33c1′ is pentagonal.

As shown in FIG. 3A and FIG. 3B, a light-emitting unit 21 is soldered on each pair of the bonding pads 33a1, 33a2 in each region R of the RDL 3B, and its detailed structure can be referred to FIG. 4 and relative descriptions. In an embodiment, three light-emitting units 21, 21′, and 21″ are in each region R, wherein the three light-emitting units 21, 21′, and 21″ may emit light with different colors, such as red light with wavelength between 610 nm and 640 nm, green light with wavelength between 510 nm and 540 nm, and blue light with wavelength between 440 nm and 470 nm. The structures of the light-emitting units 21, 21′, and 21″ may be identical or similar, referring to detail description of FIG. 4. In another embodiment, four or more light-emitting units for emitting different wavelengths may be placed in each region R. Besides of the light-emitting units 21, 21′, and 21″ for emitting red, green, and blue light, a light-emitting unit for emitting cyan light with wavelength between 470 nm to 510 nm or a light-emitting unit for emitting infrared light with wavelength higher than 660 nm can be further included in each region R to provide a wider color gamut or functions other than displaying (e.g., sensing or heating).

FIG. 4 is a cross-sectional view of the light-emitting unit 21 soldered to the bonding pads 33a1, 33a2. The light-emitting unit 21 includes an epitaxial stack 21a, a first electrode 21b, and a second electrode 21c. The epitaxial stack 21a includes a p-type semiconductor layer 21p, an n-type semiconductor layer 21n, and a light-emitting layer 21e between the p-type semiconductor layer 21p and the n-type semiconductor layer 21n. The first electrode 21b and the second electrode 21c respectively connect to the p-type semiconductor layer 21p and the n-type semiconductor layer 21n to introduce electric current to the epitaxial stack 21a so that the light-emitting layer 21e emits light. A gap 21g is between the first electrode 21b and the second electrode 21c. In an embodiment, any length W of the light-emitting unit 21 equals to or less than 100 μm, and the width Wp of the first electrode 21b and the width Wn of the second electrode 21c are greater than 30 μm so the gap 21g is less than 30 μm. The width Wp of the first electrode 21b and the width Wn of the second electrode 21c are greater than 30 μm for ensuring stability and high quality of subsequent process of soldering the first and second electrode 21a, 21b on the bonding pads 33a1, 33a2 of the RDL 3B. The method of soldering the light-emitting unit 21 to the bonding pads 33a1, 33a2 includes providing a connecting structure 40 between each of the light-emitting unit 21 and the corresponding bonding pads 33a1, 33a2 to provide electrical and physical connection. The connecting structure 40 includes a first electrical connecting portion 40a, a second electrical connecting portion 40b, and a protective portion 40c. In an embodiment, the first electrical connecting portion 40a electrically connects to the first electrode 21b and the bonding pad 33a1, the second electrical connecting portion 40b electrically connects to the second electrode 21c and the bonding pad 33a2, and the protective portion 40c surrounds the first electrical connecting portion 40a and the second electrical connecting portion 40b. In an embodiment, profile 40S of the first electrical connecting portion 40a and the second electrical connecting portion 40b may be a smooth surface or an uneven surface. In an embodiment, most of the first electrical connecting portion 40a and the second electrical connecting portion 40b are made by conductive materials. Moreover, in a cross-sectional view, each of the first electrical connecting portion 40a and the second electrical connecting portion 40b may include air voids or resin particles with a number less than 10, 50, or 100. In another embodiment, the entire first electrical connecting portion 40a and the second electrical connecting portion 40b may be made from conductive material.

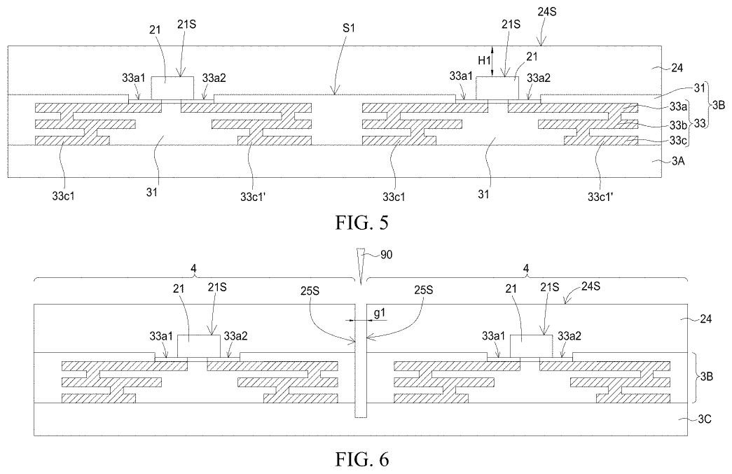

As shown in FIG. 5, a light-transmitting layer 24 covers on the upper surface S1 of the RDL 3B and the upper surface 21S of the light-emitting unit 21. The light-transmitting layer 24 includes an upper surface 24S opposite to the upper surface S1 of the RDL 3B, and a height difference H1 between the upper surface 24S and the upper surface 21S of the light-emitting unit 21 is between 1 μm and 100 μm, preferably between 10 μm and 30 μm.

The light-transmitting layer 24 can protect the light-emitting unit 21 and the connecting structure 40. The light emitted from the light-emitting unit 21 may pass through the light-transmitting layer 24. In an embodiment, the transmittance of the light-transmitting layer 24 for the light with wavelengths between 440 nm and 470 nm, between 510 nm and 540 nm, and between 610 nm and 640 nm is higher than 80%. In an embodiment, the refractive index of the light-transmitting layer 24 is between 1.3 and 2.0. In another embodiment, the refractive index of the light-transmitting layer 24 is between 1.35 and 1.7. The material of the light-transmitting layer 24 may be resin, ceramic, glass, or a combination thereof. In an embodiment, the material of the light-transmitting layer 24 is thermal curing resin, and the thermal curing resin may be epoxy or silicone. In an embodiment, the light-transmitting layer 24 is made of silicone, and the composition of the silicone may be adjusted by desired physical properties or optical properties. In an embodiment, the light-transmitting layer 24 is made of aliphatic-containing silicone resins, such as methylsiloxane compounds, so the light-transmitting layer 24 has greater ductility to withstand the thermal stress derived from the light-emitting unit 21.

As shown in FIG. 6, the RDL 3B is transferred from the temporary substrate 3A to another temporary substrate 3C, wherein the transferring process includes separating the RDL 3B with the temporary substrate 3A by light, heating, and/or mechanical force, and then affix the lower surface S2 of the RDL 3B with the temporary substrate 3C. In an embodiment, the temporary substrate 3C is a soft substrate with an adhesive layer (such as a tape) for facilitate subsequent process to cut the RDL 3B. Afterwards, a cutting tool 90 is provided to cut the light-transmitting layer 24 and the RDL 3B from the upper surface 24S of the light-transmitting layer 24 downwardly, and a side surface 25S is exposed to separate the regions R (as shown in FIG. 3B) as independent RDL pixel packages 4, wherein the RDL pixel packages 4 only uses RDL 3B for bonding the light-emitting units 21, 21′, and 21″. In the cutting step, the temporary substrate 3C is not cut, and the RDL pixel packages 4 are adhered on the temporary substrate 3C.

As shown in FIG. 7A, a carrier 5′ is provided. The carrier 5′ includes an upper surface 5S1, a lower surface 5S2 opposite to the upper surface 5S1, a plurality of upper conductive pads 53a on the upper surface 5S1, and a plurality of lower conductive pads 53c on the lower surface 5S2. The carrier 5′ includes printed circuit board, such as Bismaleimide-Triazine (BT) circuit board or High Density Interconnect (HDI) circuit board. The material of the upper conductive pad 53a and the lower conductive pad 53c may be metal, such as Cu, Sn, Al, Ag, Au, an alloy thereof, or a stack thereof. Between adjacent upper conductive pads 53a, there is a minimum gap 53g1 between 30 μm and 100 μm for corresponding to the lower electrodes 33c1 and 33c1′ of the RDL pixel package 4. Between adjacent lower conductive pads 53c, there is a minimum gap 53g2 greater than 100 μm sufficient for subsequent Surface Mount Technology (SMT) process.

In FIG. 7A, the lower electrodes 33c1, 33c1′ of the RDL pixel package 4 are electrically connected to the upper conductive pads 53a of the carrier 5′ by a conductive structure (not shown), wherein the conductive structure includes metal solder, such as solder paste and conductive adhesives (e.g., anisotropic conductive adhesives). The structure in FIG. 7A is formed by a mass transfer process to separate the RDL pixel packages 4 from the temporary substrate 3C, and then transfer and affix the RDL pixel packages 4 to the carrier 5′. The mass transfer process means the number of the RDL pixel packages 4 transferred from the temporary substrate 3C to the carrier 5′ at the same time is greater than 10, 100, or 1000. In this step, a gap g2 between adjacent RDL pixel packages 4 on the carrier 5′ is greater than a gap g1 between adjacent RDL pixel packages 4 on the temporary substrate 3C (as shown in FIG. 6). In an embodiment, in the mass transfer process, the arrangement of the RDL pixel packages 4 on the temporary substrate 3C and the arrangement of the RDL pixel packages 4 on the carrier 5 are different. In other words, when the RDL pixel packages 4 are transferred from the temporary substrate 3C to the carrier 5, the arrangement of the RDL pixel packages 4 are changed regularly or irregularly. The purpose of changing the arrangement of the RDL pixel packages 4 is to ensure the photoelectric properties (e.g., wavelength or luminous efficiency) are uniformly distributed on the carrier 5.

Afterwards, a protective layer 54 covers the upper surface 5S1 of the carrier 5′ and surrounds the RDL pixel package 4 for protecting the RDL pixel package 4, and the material and the property of the protective layer 54 may be identical to or different from that of the light-transmitting layer 24 of the RDL pixel package 4. In an embodiment, the protective layer 54 has an upper surface 54S, which is coplanar with the upper surface 24S of the RDL pixel package 4. In another embodiment, the upper surface 54S of the protective layer 54 is about 1 μm to 30 μm higher than the upper surface 24S of the RDL pixel package 4.

As shown in FIG. 7B, the structure shown in FIG. 7A is separated to form a plurality of multi-substrate pixel packages 6A with a cutting tool 90 (as shown in FIG. 7A) to cut the protective layer 54 and the carrier 5′ from the upper surface 54S of the protective layer 54 downwardly. The multi-substrate pixel packages 6A has a substrate stack structure which includes the carrier 5 and the RDL 3B, and the details of the carrier 5 and the RDL 3B could be refer to the above. In another embodiment, the cutting tool 90 may sequentially cut the carrier 5′ and the protective layer 54 from the lower surface 5S2 of the carrier 5′. As shown in FIG. 7B, after the cutting tool 90 cut downwardly from the upper surface 54S of the protective layer 54, the multi-substrate pixel package 6A has a lateral surface 5S3, and the lateral surface 5S3 includes side surfaces of the carrier 5 and the protective layer 54. As shown in FIG. 7A, the cutting tool 90 may be a cutting blade having a back portion 901 and a belly portion 902. The belly portion 902 faces the object to be cut, the back portion 901 faces away from the object to be cut, and the width of the belly portion 902 is less than the width of the back portion 901. If the cutting blade in FIG. 7A is used as a cutting tool 90, an angle θ between the lateral surface 5S3 and the lower surface 5S2 of the multi-substrate pixel package 6A is not a right angle. When the cutting tool 90 cuts downwardly from the upper surface 54S of the protective layer 54, the angle θ is less than 90 degrees, as shown in FIG. 7B. In another embodiment, when the cutting tool 90 cuts from the lower surface 5S2 of the carrier 5, the angle θ is greater than 90 degrees (not shown). In an embodiment, each of the multi-substrate pixel packages 6A includes at least one RDL pixel package 4.

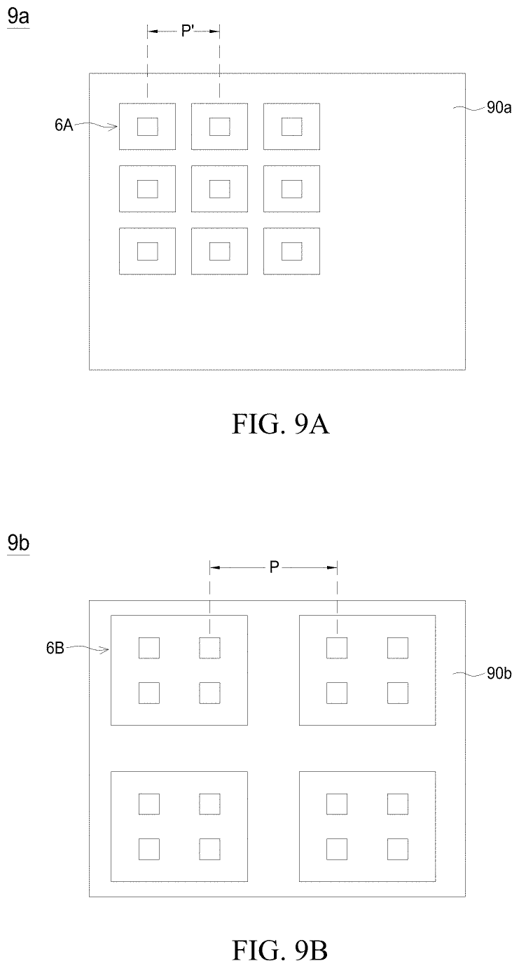

FIG. 7C is a top view of the multi-substrate pixel package 6A. As shown in FIG. 9A, the multi-substrate pixel packages 6A are arranged on a unit circuit board 90a with a constant pixel pitch P′ to form a display unit 9a. The unit circuit board 90a includes HDI circuit board with electrodes (not shown) for connecting the lower conductive pads 53c of the multi-substrate pixel packages 6A. The method of arranging the multi-substrate pixel packages 6A on the unit circuit board 90a may be soldering, such as surface mount technology (SMT) process. The size of the electronic elements suitable for use in the SMT process is preferably greater than 200 μm*200 μm, so the size of the pixel packages 6A should be greater than 200 μm*200 μm. As described above, the light-emitting units 21, 21′, and 21″ with the gap 21g between the electrodes less than 30 μm can only be soldered on the RDL 3B. If each of the multi-substrate pixel packages 6A uses the RDL 3B with an area greater than 200 μm*200 μm as the carrier 5′, the cost can be increased significantly. Therefore, in this embodiment, the light-emitting units 21, 21′, and 21″ of the multi-substrate pixel package 6A with the gap 21g between the electrodes less than 30 μm are soldered on the RDL 3B with a smaller area, and then the lower electrodes 33c1, 33c1′ of the RDL 3B having the electrode gap 33g2 greater than 30 μm are soldered on the carrier 5 with a greater area and low-cost material to reduce the usage area of the RDL 3B to significantly reduce the cost.

FIG. 8A and FIG. 8B show the process of the multi-substrate pixel package 6B. The process of the multi-substrate pixel package 6B is substantially identical to the process of the multi-substrate pixel package 6A, and the difference is that the multi-substrate pixel package 6B includes a plurality of RDL pixel packages 4. The number of the RDL pixel packages 4 illustrated or shown are only examples, and the present disclosure is not limited thereto. As shown in FIG. 8A, adjacent RDL pixel packages 4 are affixed on the carrier 5′ with a predetermined pixel pitch P, wherein the predetermined pixel pitch P means the distance between the light-emitting units 21 that emit light of the same color of adjacent RDL pixel packages 4, and the predetermined pixel pitch P is identical to the distance between the pixels of a display unit 9b (shown in FIG. 9B) made with the multi-substrate pixel package 6B later. As shown in FIG. 8A, the cutting tool 90 is provided to cut the protective layer 54 and the carrier 5′ downwardly from the upper surface 54S of the protective layer 54 to form a plurality of multi-substrate pixel packages 6B, as shown in FIG. 8B, wherein each of the multi-substrate pixel packages 6B has a plurality of RDL pixel packages 4 with a pixel pitch P between two adjacent RDL pixel packages 4. As shown in FIG. 8C, in a top view of the multi-substrate pixel package 6B, a plurality of RDL pixel packages 4 are arranged in a 2*2 array, and the distances between the centers of the adjacent RDL pixel packages 4 in the X direction and the Y direction are the pixel pitch P.

As shown in FIG. 9B, the multi-substrate pixel packages 6B are soldered on a unit circuit board 90b with a constant pitch to form a display unit 9b later, wherein adjacent RDL pixel packages 4 have an identical pixel pitch P between thereof.

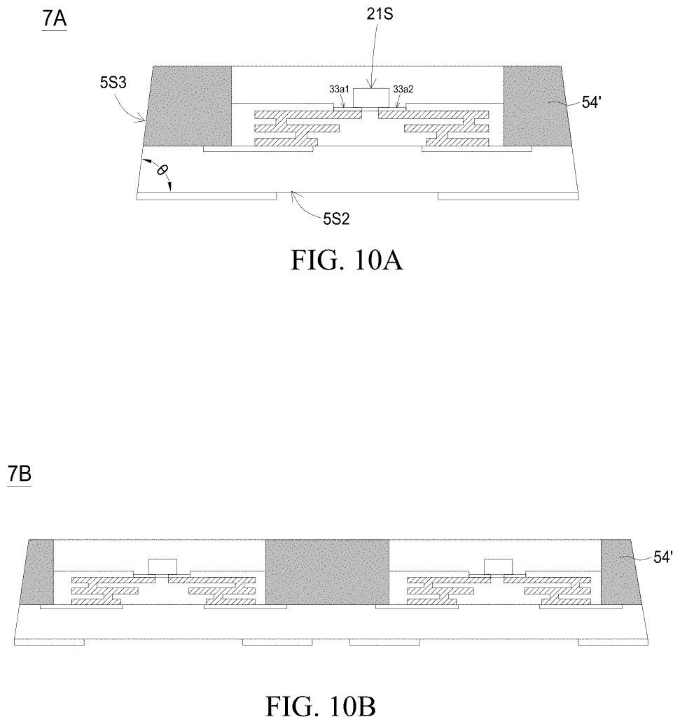

FIG. 10A to FIG. 10B show structures of a pixel package 7A and a pixel package 7B in accordance with another embodiment. The difference between the pixel package 7A and the multi-substrate pixel package 6A and the difference between the pixel package 7B and the multi-substrate pixel package 6B are that the protective layer 54 is replaced by a dark protective layer (light absorption layer) 54′, wherein the difference between the materials of the dark protective layer 54′ and the protective layer 54 is that the dark protective layer 54′ further includes about 1 wt % to 10 wt % dark powder (such as carbon black) to absorb side light of the RDL pixel packages 4 for decreasing the cross talk between the RDL pixel packages 4 for increasing the display contrast.

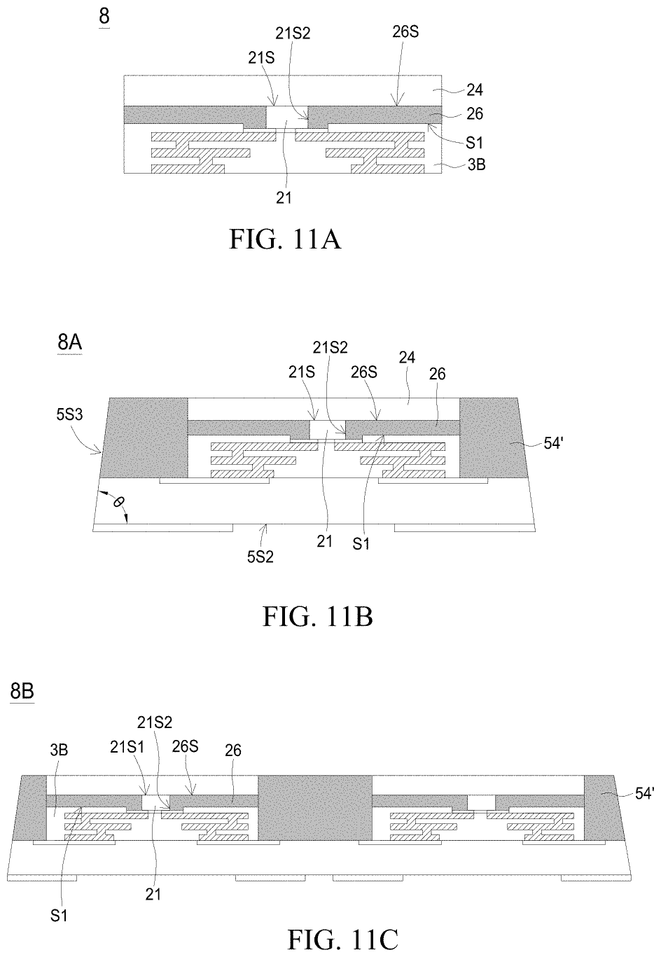

FIG. 11A to FIG. 11C show structures of a pixel package 8, a pixel package 8A, and a pixel package 8B in accordance with another embodiment. The difference between the pixel package 8 and the RDL pixel package 4 is that the pixel package 8 further includes a light absorption layer 26 between the light-transmitting layer 24 and the RDL 3B, and the light absorption layer 26 covers the upper surface S1 of the RDL 3B and the sidewall 21S2 of the light-emitting unit 21, and exposes the upper surface 21S. In an embodiment, the light absorption layer 26 is in contact with the sidewall 21S2 of the light-emitting unit 21 and the upper surface S1 of the RDL 3B for forming a contact interface 26S with the light-transmitting layer 24, and the contact interface 26S is an uneven surface. In an embodiment, the contact interface 26S is a concave surface and lower than the upper surface 21S of the light-emitting unit 21. In another embodiment, the contact interface 26S is a convex surface, but still lower than the upper surface 21S of the light-emitting unit 21.

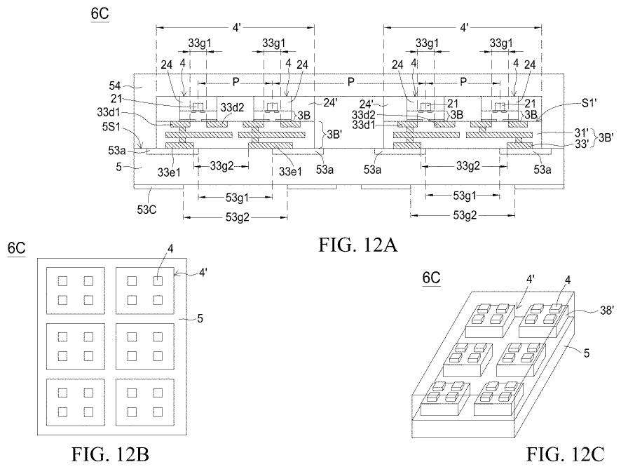

In accordance with an embodiment, FIG. 12A to FIG. 12C show a multi-substrate pixel package 6C with 24 RDL pixel packages 4 arranged in a 6*4 array, wherein FIG. 12A is a cross-sectional view of the multi-substrate pixel package 6C, FIG. 12B is a top view of the multi-substrate pixel package 6C, and FIG. 12C is a perspective view of the multi-substrate pixel package 6C. The multi-substrate pixel package 6C has a substrate stack structure which includes the carrier 5, a RDL 3B′ and the RDL 3B, and the details of the carrier 5, the RDL 3B′ and the RDL 3B are described after. As shown in FIG. 12A to FIG. 12C, the multi-substrate pixel package 6C includes a carrier 5, a plurality of RDL pixel packages 4′ arranged in a 3*2 array and soldered on the carrier 5, and a protective layer 54 covering the RDL pixel packages 4′ on the upper surface 5S1 of the carrier 5 for protecting the RDL pixel packages 4′. The material of the protective layer 54 and the carrier 5 are identical to that of the protective layer 54 and the carrier 5 of the multi-substrate pixel packages 6A and 6B. In an embodiment, the carrier 5 is a HDI circuit board formed with conventional printed circuit board processes for reducing the cost of the multi-substrate pixel package 6C, so the carrier 5 has wider metal line and larger electrode gaps than that of the RDL 3B, 3B′. For example, a minimum gap 53g1 between adjacent upper conductive pads 53a is greater than 100 μm, and a minimum gap 53g2 between adjacent lower conductive pads 53c is greater than 150 μm.

As shown in FIG. 12A, which is a cross-sectional view of the multi-substrate pixel package 6C, the RDL pixel package 4′ includes another RDL 3B′, a plurality of RDL pixel packages 4 arranged in an array and soldered on the RDL 3B′, and a light-transmitting layer 24′ covering or surrounding the RDL pixel packages 4 on the upper surface S1′ of the RDL 3B′. In an embodiment, in the RDL pixel package 4′, the array of the RDL pixel packages 4 can be 2*2, 1*2, 2*3, 3*3, or m*n, wherein “m” and “n” are positive integer. The description of the RDL pixel packages 4 can be referred to FIG. 6 and related paragraphs. The light-transmitting layer 24′ is identical to the aforementioned light-transmitting layer 24 and used for protecting the RDL pixel packages 4. The RDL 3B′ is the same with or similar to the aforementioned RDL 3B and includes an insulating layer 31′ and a circuit structure 33′, wherein the circuit structure 33′ includes a plurality of circuit layers and a plurality of vias for electrically connecting the circuit layers. The materials of the insulating layer 31 of the RDL 3B may be identical or different to the material of the insulating layer 31′ of the RDL 3B′.

In accordance with another embodiment, the insulating layer 31 of the RDL 3B is Ajinomoto Build-up Film (ABF). Since the ABF is suitable for semiconductor-level processes, bonding pads 33a1, 33a2 (as shown in FIG. 2B) with a gap 33g1 less than 30 μm, which is suitable for connecting a chip with a gap of less than 30 μm between the electrodes (e.g., mini LED or micro LED), and lower electrodes 33c1, 33c1′ (as shown in FIG. 2B) with a gap of 33g2 between 50 μm and 100 μm can be manufactured. The insulating layer 31′ of the RDL 3B′ can be made of polyimide (PI), which can be used for making a circuit structure 33′ with a relative low-cost laser process. The RDL 3B′ includes a plurality of bonding pads 33d1 and 33d2 used for connecting to the RDL pixel packages 4, and a plurality of lower electrodes 33e1 used for electrically connecting to the upper conductive pads 53a of the carrier 5. The minimum gap 33g1 between adjacent bonding pads 33d1 and 33d2 is between 50 μm and 100 μm for corresponding lower electrodes 33c1 and 33c1′ of the RDL pixel packages 4. The minimum gap 33g2′ between adjacent lower electrodes is greater than 100 μm for corresponding to the minimum gap 53g1 between two adjacent upper conductive pads 53a. The process of affixing the RDL pixel packages 4 to the RDL 3B′ may use the processes and materials recited in FIG. 2A to FIG. 6 and related paragraphs.

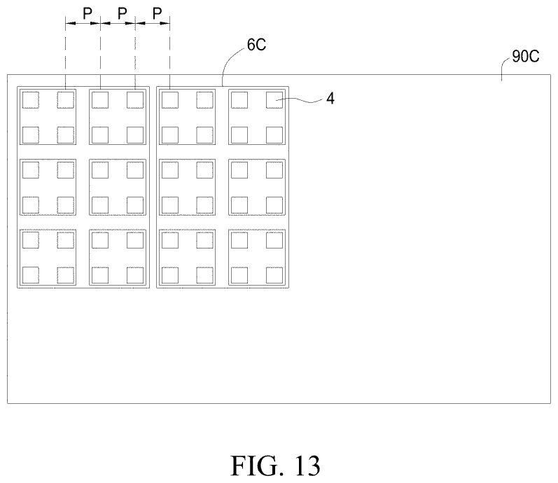

In the cross-sectional view of the multi-substrate pixel package 6C, as shown in FIG. 12A, the distance between any two adjacent RDL pixel packages 4 is the pitch P. A display unit 9C is shown in FIG. 13, wherein any two adjacent multi-substrate pixel packages 6C are affixed on a unit circuit board 90C with a constant gap J, and the distance between any two adjacent RDL pixel packages 4 is the pixel pitch P.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

What is claimed is:

1. A light-emitting device, comprising:
a first carrier, comprising:
a first surface;
a second surface;
a side surface between the first surface and the second surface;
a plurality of upper conductive pads on the first surface; and
a plurality of lower conductive pads under the second surface;
an RDL pixel package, comprising:
a re-distribution layer (RDL) comprising a plurality of bonding pads and a plurality of lower electrodes;
a plurality of light-emitting units located on the re-distribution layer and connected to the plurality of bonding pads;
a light-transmitting layer located on the re-distribution layer and covering the plurality of light-emitting units;
an upper surface;
a lower surface; and
a lateral surface located between the upper surface and the lower surface, and the RDL pixel package is located on the first surface of the first carrier and electrically connected to the plurality of upper conductive pads of the first carrier; and
a protective layer covering the first surface of the first carrier and in contact with the lateral surface of the RDL pixel package;
wherein the plurality of lower electrodes and the plurality of upper conductive pads of the first carrier are connected, and the distance between any two adjacent bonding pads is less than 30 μm.

2. The light-emitting device as claimed in claim 1, wherein the plurality of light-emitting units is able to emit light, the light-transmitting layer of the RDL pixel package is penetrable by the light emitted from the light-emitting units, and the protective layer is not penetrable by the light emitted from the light-emitting units.

3. The light-emitting device as claimed in claim 1, wherein the protective layer comprises a first upper surface and a first side surface, the first upper surface is higher than or level with the RDL pixel package, and an angle between the first surface and the first side surface does not equal to 90 degrees.

4. The light-emitting device as claimed in claim 1, wherein a gap between any two adjacent lower electrodes in the re-distribution layer is greater than 30 μm.

5. The light-emitting device as claimed in claim 1, wherein any one of the emitted from the light-emitting units has a length less than 100 μm.

6. The light-emitting device as claimed in claim 1, wherein the RDL pixel package further comprises a light absorption layer between the re-distribution layer and the light-transmitting layer and in contact with the plurality of emitted from the light-emitting units.

7. The light-emitting device as claimed in claim 6, wherein the material of the light absorption layer and the material of the protective layer are substantially identical.

8. The light-emitting device as claimed in claim 6, wherein the light absorption layer comprises a second upper surface, the plurality of emitted from the light-emitting units comprises a third upper surface, and the second upper surface is not higher than the third upper surface.

9. The light-emitting device as claimed in claim 1, wherein the plurality of emitted from the light-emitting units is capable of emitting light with different wavelengths.

10. The light-emitting device as claimed in claim 1, wherein the side surface of the first carrier is a flat surface.

11. The light-emitting device as claimed in claim 1, wherein an angle between the side surface of the first carrier and the second surface is greater than 90 degrees.
